(19) United States
(12) Patent Application Publication
(10) Pub. No.: US 2025/0324536 A1
(43) Pub. Date: Oct. 16, 2025

(54) Connecting device for an automation platform and automation platform

(71) Applicant: Murrelektronik GmbH, Oppenweiler (DE)

(72) Inventors: Luca Hoffmann, Backnang (DE); Olaf Prein, Lugde-Rischenau (DE); Heiko Feisst, Schlierbach (DE); Nils Matheis, Auenwald (DE)

(21) Appl. No.: 19/170,983

(22) Filed: Apr. 4, 2025

(30) Foreign Application Priority Data
Apr. 12, 2024 (DE) 10 2024 110 300.0

(51) Int. Cl. H05K 7/14; H01R 4/48

(52) U.S. Cl. CPC H05K 7/1468; H01R 4/4821

(57) ABSTRACT

The invention relates to a connecting device for an automation platform, comprising a first contact reception element arranged in a first layer and designed to provide a first contacting with a first contacting element of a functional module corresponding to the first contact reception element, and a second contact reception element, arranged in a second layer, different from the first layer, providing a second contacting with a second contacting element of the functional module corresponding to the second contact reception element, wherein the first contact reception element is designed to provide a main energy flow, auxiliary energy flow, or data flow to the functional module via the first contacting element, and wherein the second contact reception element is designed to provide a main energy flow, auxiliary energy flow and data flow to the functional module via the second contacting element.

### RELATED APPLICATION(S)

This application claims the benefit of German Application DE, 10 2024 110 300.0 (filed on Apr. 12, 2024), the entirety of which is incorporated by reference herein.

### FIELD OF THE INVENTION

The present invention relates to a connecting device for an automation platform as well as to an automation platform and a plant with such a connecting device.

### BACKGROUND

It is known from the state of the art that modular automation solutions are used to supply electrical devices in an industrial plant with energy via power lines and to control them via control lines, such as fieldbus lines. Modularity is often achieved by using individual, independent functional modules that may be individually configured and combined. This has the advantage that the automation solutions may be flexibly adapted to the respective requirements of the industrial plant, thus ensuring high efficiency and cost-effectiveness.

The publication US 2013/0342152 A1 discloses a multi-shaft motor drive device in which at least one amplifier module, a control substrate and a power substrate are provided.

The publications WO 2012/000808 A1, WO 2023/088883 A1 and EP 2 728 673 B1 disclose further solutions within the same category.

It is often a problem with conventional solutions that the assembly of functional modules of an automation platform may be time-consuming and error-prone. It is therefore a task of the present invention to at least partially eliminate the disadvantages described above. In particular, it is a task of the present invention to improve the connection of functional modules with a common connecting device.

### SUMMARY

The object of the invention is a connecting device with the features of claim 1 as well as an automation platform with the features of claim 9 and a plant with the features of claim 15. Further features and details of the invention are apparent from the respective subclaims, the description and the drawings. Features and details that are described in connection with the connecting device according to the invention naturally also apply in connection with the automation platform according to the invention and the plant and vice versa, so that reference is or may always be made mutually to the individual aspects of the invention with regard to the disclosure.

The object of the invention is, in particular, a connecting device for an automation platform.

The connecting device according to the invention may comprise:
a first contact reception element which is arranged in a first layer and which is designed to provide a first contacting with a first contacting element of a functional module corresponding to the first contact reception element, i.e. the first contacting element corresponds to the first contact reception element, and/or
a second contact reception element, which is arranged in a second layer, which differs from the first layer and is preferably angled to the first layer, and which is designed to provide a second contacting with a second contacting element of the functional module corresponding to the second contact reception element.

Furthermore, the first contact reception element may be designed to provide at least one of a main energy flow, an auxiliary energy flow and a data flow to the functional module via the first contacting element.

Furthermore, the second contact reception element may be designed to provide at least one of a main energy flow, an auxiliary energy flow and a data flow to the functional module via the second contacting element.

The first contact reception element may optionally be designed to provide at least one of a main energy flow, an auxiliary energy flow and a data flow, i.e. the main energy flow and/or the auxiliary energy flow and/or the data flow, to the functional module via the first contacting element. Furthermore, the second contact reception element may optionally be designed to provide at least one further of a main energy flow, an auxiliary energy flow and a data flow, i.e. in particular the main energy flow and/or the auxiliary energy flow and/or the data flow, but preferably not the flow that is already provided by the first contact reception element, to the functional module via the second contacting element.

A flow may preferably be understood as an electrical flow, i.e. preferably an electrical current flow for power supply and/or data exchange. In contrast to the main and/or auxiliary energy flow, the data flow may not be intended primarily for power supply, but for data exchange.

Advantageously, the connecting device and/or the automation platform and/or a respective automation platform according to the invention may serve for automation at an industrial plant such as an automation plant and/or the industrial plant according to the invention.

Accordingly, the power supply via the main and/or auxiliary energy flow may serve to supply power to at least one component at this plant and/or may be provided to provide at least one process and preferably automation process. A data exchange via the data flow may preferably also be used for automation.

An automation platform, for which the connecting device according to the invention is set up and designed, may be understood as hardware, possibly with associated software, in order to automate certain processes in an electrical plant. For example, motors, preferably servomotors, are actuated and used to move a robot arm or control a conveyor belt. The connecting device may be at least part of the automation platform in order to connect one or more functional modules to it and/or to each other, and in this way provide various modular functions for the automation, such as controlling the motors. This may have the advantage of enabling the connecting device with the functional modules to connect and/or control and/or evaluate a large number of devices and components in an electrical plant in order to ensure smooth and efficient automation.

The modularity may be achieved by designing the functional modules as individual modules, in particular independent modules, each with its own module housing and electronics that allow the modules to be individually configured and functionally combined with other functional modules. The functional modules may also have data and/or power supply interfaces to each other and/or to devices and/or components of the electrical plant. It is possible, for example, that at least one of the functional modules connected to the connecting device is able to establish a wired and/or wireless connection to a device and/or component to be controlled. At least one of the functional modules connected to the connecting device may also be designed to provide a power supply for a device to be controlled and/or a component and/or the other connected functional modules.

In the connecting device according to the invention, a first contact reception element may initially be provided, which is arranged in a first layer of the connecting device. The first contact reception element may be designed to provide a first contacting with a first contacting element of such a functional module corresponding to the first contact reception element. A second contact reception element may also be provided, which is arranged in a second layer of the connecting device, which differs from the first layer and is preferably angled to the first layer. The second contact reception element may be designed to provide a second contacting with a second contacting element of the same functional module that corresponds to the second contact reception element. In the present case, corresponding means, in particular, matching and/or complementary to one another.

The connecting device according to the invention may therefore have two, in particular different, contact reception elements in two different and/or mutually angled layers, which are designed to receive two corresponding contacting elements of one and the same functional module and to establish contacting with these.

The connecting device according to the invention may furthermore have three, in particular different, contact reception elements in two or three different and/or mutually angled layers, which are designed to receive three contacting elements of one and the same functional module, each corresponding thereto and in particular differing from one another, and to establish a contacting with these.

The contact reception elements, in particular the first and/or second and/or third contact reception element, may differ from one another, for example, in terms of their geometric design and/or size and/or area and/or in terms of their electrical properties (such as maximum transmittable power) and/or in terms of their coding for a connection and preferably plug connection. In particular, coding is understood to mean a clear assignment of the contact reception elements to a specific connection/plug connection. This may be achieved by a specific shape, color or labeling of the contact reception elements. The contacting elements may differ from each other in a corresponding manner.

In the present case, contacting means in particular the provision and/or establishment of an electrical, in particular signal and/or power connection. In the present case, corresponding means in particular that the two elements fit together, in particular functionally and/or spatially and physically, are compatible with each other, are shaped identically or complementarily to each other and/or are designed to complement each other.

Furthermore, the term “reception”, also referred to as receptacle, in the first and second and possibly third contact reception element serves in particular initially to conceptually distinguish these elements from the corresponding first and second and possibly third contacting element of the functional module and does not necessarily comprise a physical receptacle of the first and/or second contacting element, but the first and second contact reception element merely establishes contacting with the respective contacting element of the functional module via contacting and/or touching.

However, it may also be provided that the first and/or second and/or third contact reception element comprises one or more receiving devices which are designed to physically receive the first and/or second and/or third contacting element, in particular to engage therewith, snap into place and/or interlock, as will be described in the further course. In particular, one or both of the first and/or second contact reception element may have a plug receptacle and one or both of the first and/or second contacting element may have a plug corresponding thereto or vice versa. The foregoing also applies to the third contact reception element.

In particular, the angle between the two layers of the connecting device may be greater than 15°, greater than 30°, greater than 45°, greater than 60°, greater than 75°, greater than 80° or greater than 85°. Alternatively or additionally, the angle between the two layers of the connecting device may be less than 165°, less than 150°, less than 135°, less than 120°, less than 105°, less than 100° or less than 95°. In particular, the angle is between 85° and 95° and is also approximately, substantially or exactly 90°. In particular, the first layer, in which or along which the first contact reception element is arranged, is in a layer approximately, substantially or exactly parallel to a ground or floor and the second layer, in which or along which the second contact reception element is arranged, is in a layer approximately, substantially or exactly perpendicular to a ground or floor.

Furthermore, it may be provided that the first contact reception element is designed to provide at least one of a main energy flow, an auxiliary energy flow and/or a data flow to the functional module via the first contacting element. Alternatively or additionally, it may be provided that the second contact reception element is designed to provide at least one further, in particular another, of a main energy flow, an auxiliary energy flow and/or a data flow to the functional module via the second contacting element. In particular, the main energy flow, auxiliary energy flow and/or data flow provided by the first contact reception element may differ from the main energy flow, auxiliary energy flow and/or data flow provided by the second contact reception element, in particular in terms of flow type and/or energy strength, as will also be described in the further course. For example, the first contact reception element may provide an auxiliary energy flow to the first contacting element and the second contact reception element may provide a main energy flow to the second contacting element.

The connecting device according to the invention may thereby advantageously contact a functional module in two layers different from each other and in particular also securely fasten it in order to provide one or more of a main energy flow, an auxiliary energy flow and/or a data flow in the two layers to the functional module.

Within the scope of the invention, it may be provided that the first contact reception element and/or the second contact reception element and/or the third contact reception element are designed to form a plug connection and/or comprise a pin-socket-contacting. In particular, only one of the first contact reception element and the second contact reception element may comprise a pin-socket-contacting, and furthermore only the first contact reception element. A pin-socket-contacting is a type of contacting in which one or more pins and/or rods, which may also be referred to as male contacting, are inserted into one or more corresponding sockets and/or plug receptacles, which may also be referred to as female contacting, to produce a plug connection and engage therein, for example by static friction. In particular, the contact reception element, further in particular exclusively the first contact reception element, comprises one or more sockets and/or receptacles for receiving one or more pins and/or rods and the contacting element has one or more pins and/or rods which are received in the socket(s) and/or receptacle(s) of the contact reception element. This enables a particularly secure contacting.

Alternatively or additionally, it may be provided that the first contact reception element and/or the second contact reception element and/or the third contact reception element comprises a spring contacting. A spring contacting is a type of contacting in which at least one of the contact reception element and the contacting element is formed as a spring, at least in sections. The spring may be pretensioned in a certain direction by shaping, in particular in an insertion direction, as will be described further on. Additionally or alternatively, it may be provided that the first contacting element and/or the second contacting element and/or the third contacting element of the functional module comprises a spring contacting. In this case, the first contact reception element and/or the second contact reception element and/or the third contact reception element may also be designed as an surface (or area) contacting or alternatively also as a spring contacting, which in each case interacts with a spring contacting of the functional module or vice versa. This enables a particularly flexible contacting.

Of further advantage, it may be provided that the first layer and the second layer of the connecting device are arranged relative to each other such that they enable insertion of the functional module in an insertion direction which is substantially perpendicular to one of the first layer and the second layer, and wherein the spring contacting is arranged and formed such that it springs in the insertion direction or counter thereto. As explained above, the first and second layers may in particular be arranged approximately, substantially or exactly at right angles to one another. It may be provided that the functional module is guided to the connecting device in an insertion direction which is approximately, substantially or exactly perpendicular to the first layer and which is approximately, substantially or exactly parallel to the second layer. In particular, a spring contacting may be provided on the second contact reception element and/or on the corresponding contacting element of the functional module, which is arranged on the connecting device and/or the functional module in such a way that it springs in or against the insertion direction. This enables a particularly resilient and robust contacting.

According to an advantageous further development of the invention, it may be provided that the spring contacting provides a tolerance in the insertion direction. In particular, the spring contacting may be arranged and designed in such a way that it cushions a movement of the functional module in or against the insertion direction and maintains contacting, even if the functional module is moved in or against the insertion direction, for example by external influences. The tolerance may include a movement tolerance of, for example, 1 mm, 2 mm, 3 mm or 5 mm in and/or against the insertion direction. This also enables a particularly resilient and robust contacting.

Advantageously, within the scope of the invention, it may be provided that the spring contacting is designed as a spring clip. A spring clip is, for example, a clip composed or formed from two spring elements, in which the spring elements are arranged in opposite directions to one another, so that an empty space existing between them is tapered inwards by the pretension of the spring elements and this empty space is widened by an insertion movement, for example in the insertion direction, so that the first and/or second and/or third contacting element of the functional module may be accommodated therein and held securely. In particular, only the first contact reception element is designed as a spring clip. This enables a particularly secure contacting.

Furthermore, within the scope of the invention, it may be provided that the spring clip is arranged and designed to be spread by a spreading element of the functional module. The functional module may have a spreading element that tapers in the insertion direction, for example, or widens in the opposite direction to the insertion direction. In particular, the spreading element may be designed as a wedge. The spreading element may be arranged in particular on the first and/or second and/or third contacting element of the functional module, and in particular exclusively on the first contacting element. This enables a particularly secure mounting of the contacting or the contacting element on the contact reception element.

Alternatively or additionally, it may be provided that the first contact reception element and/or the second contact reception element and/or the third contact reception element comprises a surface (or also referred to as area) contacting. An area contacting may be designed as a planar element and, for example, interact with a corresponding surface or an area that overlaps with the area contacting at least in sections and thus establishes contacting. Alternatively or additionally, the area contacting may also interact with a spring contacting and accommodate or contact it.

In particular, means or elements may be provided on the first and/or second and/or third contact reception element or the first and/or second and/or third contacting element corresponding thereto, which enable, support and/or provide both pin-socket-contacting and spring contacting as well as area contacting. This results in a particularly error-free contacting.

According to a further advantage, it may be provided that the first contact reception element is formed differently from the second contact reception element and/or from the third contact reception element. In particular, the first contact reception element may comprise one or more of a pin-socket-contacting, a spring-contacting and an area-contacting and the second/third contact reception element may comprise one or more of a pin-socket- contacting, a spring-contacting and an area-contacting. In particular, the first contact reception element may be designed as a pin-socket-contacting and the second/third contact reception element may be designed as a spring contacting and/or as an area contacting that interacts with a spring contacting of the second/third contacting. In this way, the positive effects of the respective contacting types may be combined synergistically to produce a particularly reliable contacting.

Optionally, it may be provided that the main energy flow comprises an AC (alternating current) voltage of up to 1000 volts and/or a DC (direct current) voltage of up to 1500 volts and/or an AC voltage in the range from 70 volts to 1000 volts and/or a DC voltage in the range from 130 volts to 1500 volts, and preferably an AC voltage of essentially 400 volts or a DC voltage in the range from 650 V to 700 V.

Alternatively or additionally, it may be provided that the auxiliary energy flow comprises an AC voltage of up to 50 volts and/or a DC voltage of up to 120 volts and/or an AC voltage in the range from 0.01 volts to 50 volts and/or a DC voltage in the range from 0.01 volts to 120 volts, and preferably a DC voltage of essentially 24 V or 48 V.

Further, the data flow may comprise at least one or more signals for data exchange, preferably for providing a data bus and/or a field bus. In other words, it may be provided that the data flow is designed to transmit data and preferably fieldbus signals, preferably for communication with at least one of the devices to be controlled.

Another object of the invention is an automation platform comprising a connecting device according to one or more of the embodiments described above, as well as at least one functional module. In particular, the automation platform may comprise more than one functional module, for example two, three or more, of which at least one functional module is connected and/or connectable to the automation platform via a connecting device according to one or more of the embodiments described above.

Optionally, it may be provided that the automation platform comprises a further connecting device according to one or more of the previously described embodiments, wherein each of the at least two connecting devices is connectable to at least one functional module each, wherein the connecting devices are configured to provide at least one of the main energy flow, the auxiliary energy flow and/or the data flow to the functional modules. In particular, each of the functional modules may provide a different function for the automation platform. In particular, a first connecting device according to one or more of the embodiments described above may be provided, which is connectable and/or connected to a first functional module, and a second connecting device according to one or more of the embodiments described above, which is connectable and/or connected to a second functional module, in particular different from the first functional module. The first functional module may thereby provide a first function within the automation platform and the second functional module may provide a second function that is different from the first function.

According to a further advantage, it may be provided that the connecting devices are arranged and designed with respect to each other in such a way that they provide at least one of the main energy flow, the auxiliary energy flow and/or the data flow serially to the functional modules. In particular, the functional modules are also arranged and designed with respect to each other in such a way that they provide at least one of the main energy flow, the auxiliary energy flow and/or the data flow serially to other functional modules. In other words, the first contact reception elements and/or the second contact reception elements and/or the main energy flow, auxiliary energy flow and/or data flow connected thereto are interconnected in such a way that they are connected in series, i.e. in series with one another, so that in each case at least a main energy flow, an auxiliary energy flow and/or a data flow is provided, from which or to which the contact reception elements are connected and from which the contact reception elements are fed. In particular, the contact reception elements are connected in such a way that they may receive and forward the main energy flow, the auxiliary energy flow and/or the data flow.

Advantageously, in the invention it may be provided that the automation platform further comprises a bridge element which is connected to one of the connecting devices and which is adapted to receive at least one of the main energy flow, the auxiliary energy flow and/or the data flow and to provide it to a further connecting device. Such a bridge element, which may also be referred to as an empty element or a dummy element, may be received in one or more contact reception elements of one or more connecting devices and provide a forwarding functionality, in particular if no functional module is received in the respective connecting device. In particular, the bridge element is designed to receive one or more of the main energy flow, the auxiliary energy flow and/or the data flow in a state received by a connecting device and to forward it to a further connecting device, in particular to loop it through and/or bridge it, so that one or more of the main energy flow, the auxiliary energy flow and/or the data flow is not interrupted, in particular in the case of a serial connection. In addition, the bridge element may also protect the first and/or second and/or third contact reception element from external influences, such as dust or dirt.

It is conceivable that, in addition to the first and second contacting elements, the connecting device also comprises a third contact reception element, which is arranged in the first layer or in the second layer or in a third layer. The third contact reception element may be designed to provide a third contacting with a third contacting element of the functional module corresponding to the third contact reception element. Furthermore, the first contact reception element may be designed to provide a main energy flow to the functional module via the contacted first contacting element. The second contact reception element may be designed to provide an auxiliary energy flow to the functional module via the contacted second contacting element. The third contact reception element may be designed to provide a data flow to the functional module via the contacted third contacting element. The third layer may be different from the first and/or second layer and may preferably be spaced apart from and/or parallel to the first and/or second layer. This may also provide a non-planar, for example stepped, housing side of the connecting device for arranging at least two of the contact reception elements.

It is also conceivable that the first layer differs from the second layer in that the first layer is arranged parallel and/or offset to the second layer in such a way that the contact reception elements in the first and second layers contact the functional module via the contacting elements on opposing sides of the functional module, preferably on an upper and a lower side or on two opposing outer sides. For this purpose, some of the contact reception elements are attached to a separate coupling/adapter/cover element, for example. Contacting on the opposite sides may take place in the same contacting layer and/or from different and/or opposing contacting directions. The contacting layer may be aligned in such a way that the functional module lies in the contacting layer.

It is also conceivable that one or two of the contact reception elements is/are attached to a separate coupling/adapter/cover element, which is designed to be attached to the functional module only after contacting the other contact reception element(s) (different from the one or two contact reception elements).

Also optionally protected is a system with at least two (or at least four or at least six) automation platforms, each of which may optionally be designed as the automation platform according to the invention described above. The automation platforms may each be designed as a decentralized automation platform and may each be designed to provide partial automation functions and, in particular, a part of an overall control for the automation of an industrial plant. The automation platforms may be arranged decentrally in the field of the plant, in particular in order to jointly replace a function of a central control cabinet. Furthermore, the automation platforms may be connected to each other and/or to a central control system via an industrial communication system and/or a fieldbus.

Another object of the invention is a plant, preferably an industrial plant, with at least two (or at least four or at least six) automation platforms, each of which may optionally be designed as the automation platform according to the invention. The automation platforms may each be designed as a decentralized automation platform and may be designed accordingly to provide partial automation functions and, in particular, a part of an overall control for the automation of the industrial plant. The automation platforms may be arranged decentrally in the field of the plant, in particular in order to jointly replace a function of a central control cabinet. Furthermore, the automation platforms may be connected to each other and/or to a central control system via an industrial communication system and/or via a fieldbus. The automation platforms may thus be distributed in the field of the plant and used together to take over the function of the central control cabinet usually provided. This may have the advantage that the plant may be designed more flexibly and enables simple modification of the automation functions, particularly in the event of extensions or conversions to the plant. The decentralized arrangement of the automation platforms may also result in greater reliability, as the entire automation of the plant is not affected if one platform fails. It is also possible that the plant may be made more cost-efficient by using the automation platforms according to the invention, as the acquisition costs for a central control cabinet are eliminated and the decentralized arrangement of the platforms enables a reduction in cabling costs.

The respective automation platform according to the system according to the invention and/or the plant according to the invention may optionally comprise:
a respective connecting device and at least one functional module, the respective connecting device comprising:
   a first contact reception element which is arranged in a first layer and which is designed to provide a first contacting with a first contacting element of the functional module corresponding to the first contact reception element; and/or
   a second contact reception element, which is arranged in a second layer, which differs from the first layer and is preferably angled to the first layer, and which is designed to provide a second contacting with a second contacting element of the functional module corresponding to the second contact reception element;
   wherein preferably the first contact reception element is designed to provide at least one of a main energy flow, an auxiliary energy flow and a data flow via the first contacting element to the functional module and/or wherein the second contact reception element is designed to provide at least one further of a main energy flow, an auxiliary energy flow and a data flow via the second contacting element to the functional module.

The automation platforms may each be equipped with their own power supply and/or a cloud-based platform for remote monitoring and control and/or an integrated diagnostic function to ensure higher availability and reliability, easy troubleshooting and automatic fault detection and correction. This may have the advantage that the automation platforms may be operated independently of the site's power supply, making them suitable for use in different environments. It is also possible that the cloud-based remote monitoring and control platform will allow the automation platforms to be monitored and controlled from a remote location, increasing ease of use. The integrated diagnostic function may help to ensure that potential faults may be detected and rectified quickly and easily, making maintenance and servicing of the automation platforms easier and reducing operating costs.

Another advantage of the automation platform according to the invention is the possibility of creating and using a digital twin of the industrial plant. In particular, this is a virtual representation of the plant that is created based on real-time data and simulations. The digital twin may be used to optimize the plant by simulating different scenarios and changes before implementing them in the real plant. This may help to increase the efficiency and productivity of the plant while minimizing the risk of errors and failures. The digital twin may also be used to optimize the maintenance and servicing of the plant by identifying potential problems at an early stage and rectifying them before they lead to failures.

The automation platform according to the invention or the respective automation platform of a plant according to the invention may be designed to accommodate several functional modules in order to supply them with energy via the main and/or auxiliary energy flow and/or to control them via the data flow and/or to enable data exchange for them via the data flow.

The functional modules may provide different functions of the automation functions, in particular in the form of partial automation functions, for the automation of the industrial plant. The automation functions may comprise at least two of the following:
a motor control;
a control and/or power supply of a motor controller, which is preferably provided outside the automation platform near the motor;
a control and/or power supply of an actuator, such as, for example a motor, a valve, a stepper motor, a linear drive, a piezo actuator, a magnetic actuator, a hydraulic cylinder, a pneumatic cylinder, a flap drive, a gripper arm, a robot arm, a turntable, a conveyor belt, a crane arm, a swivel arm, a drill, a cutter, a welding device, a cutting or engraving laser, a vibration motor, a loudspeaker, an actuator in medical technology, an actuator in the automotive industry, an actuator in the aerospace industry, an actuator in robotics, an actuator in the electronics or semiconductor industry, an actuator in the food or packaging industry and/or an actuator in the textile or paper industry;
a readout and/or control and/or power supply of a sensor, preferably a proximity sensor and/or a light barrier.

Furthermore, the functional modules may also include a safety module for monitoring and safeguarding processes and/or an industrial PC and/or a fieldbus module.

### BREIF DESCRIPTION OF THE DRAWINGS

Further advantages, features and details of the invention are apparent from the following description, in which embodiments of the invention are described in detail with reference to the drawings. The features mentioned in the claims and in the description may be essential to the invention individually or in any combination. Showing:

FIG. 1 a perspective view of a connecting device according to embodiments of the invention;

FIG. 2 a perspective view of a connecting device according to further embodiments of the invention;

FIG. 3 a perspective view of a connecting device according to further embodiments of the invention; and

FIG. 4 Perspective view of a connecting device according to further embodiments of the invention.

FIG. 5 a schematic representation of an industrial plant.

In the above cited figures, the identical reference symbols are used for the same technical features, even for different embodiments.

### DETAILED DESCRIPTION

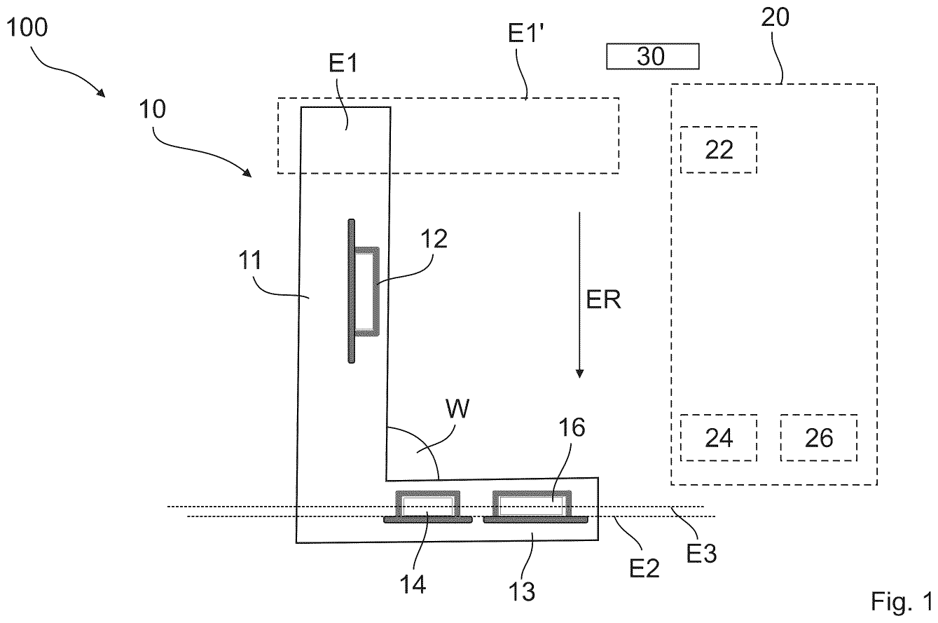

FIG. 1 illustrates a perspective view of a connecting device 10 according to embodiments of the invention.

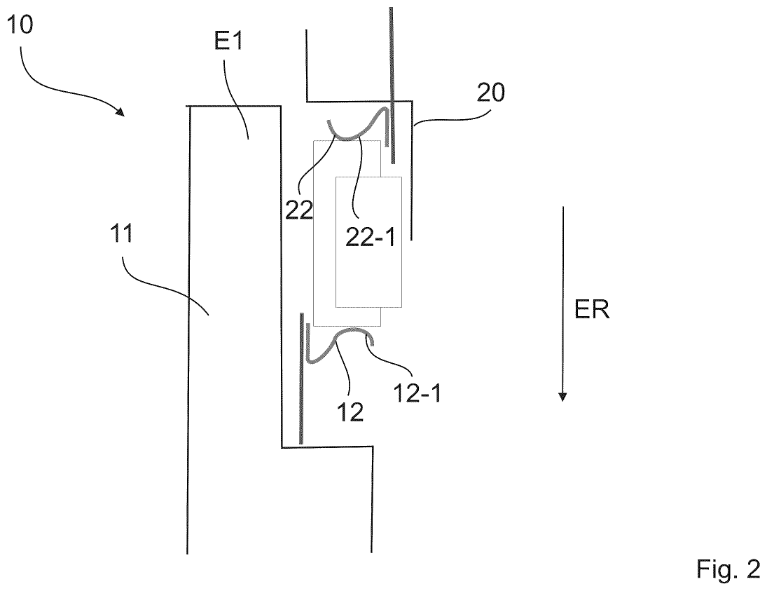

The connecting device 10 is used to connect one or more functional modules to an automation platform, which is not shown in detail here. The functional module and associated contacting elements or their embodiments are not shown in detail in this Fig. but are explained in connection with the other FIGS. 2 to 4. In particular, several of the connecting devices shown here in FIG. 1 may be provided, which are connected to each other in series. The automation platform may, for example, comprise several connecting devices and optionally one or more functional modules.

For this purpose, the connecting device 10 initially comprises a first contact reception element 12, which is arranged in a first layer E1 and which is designed to provide a first contacting with a first contacting element of a functional module corresponding to the first contact reception element 12. The connecting device 10 also comprises a second contact reception element 14, which is arranged in a second layer E2 and which is designed to provide a second contacting with a second contacting element of the functional module corresponding to the second contact reception element 14. In this FIG. 1, an optional third contact reception element 16 is also shown, which is also arranged in the second layer E2. Alternatively, the third contact reception element 16 may be arranged in the first layer E1 or in a third layer E3.

The first layer E1 may be angled in relation to the second layer E2. In particular, the first layer E1 and the second layer E2 span an angle W between them, which is essentially 90°. As may be seen in particular in this FIG. 1, the first contact reception element 12 is located in a first leg 11 and the second contact reception element 14 and the third contact reception element 16 are located in a second leg 13 of the connecting device 10, wherein the two legs are also arranged essentially perpendicular to one another or a right angle W is formed between the two legs. In other words, the two legs 11 and 13 are arranged in an L-shape relative to one another, or the connecting device 10 is essentially L-shaped.

The first contact reception element 12 is designed to provide one of a main energy flow, an auxiliary energy flow and a data flow via the first contacting element to the functional module. The second contact reception element 14 is designed to provide another of a main energy flow, an auxiliary energy flow and a data flow via the second contacting element to the functional module. In particular, the third contact reception element 16 is designed to provide a further one of a main energy flow, an auxiliary energy flow and a data flow via the first contacting element to the functional module. For example, the first contact reception element 12 provides a main energy flow, the second contact reception element 14 provides an auxiliary energy flow and the third contact reception element 16 provides a data flow via corresponding contactings to the functional module.

The main energy flow may comprise an AC voltage of up to 1000 volts and/or a DC voltage of up to 1500 volts and/or an AC voltage in the range of 70 volts to 1000 volts and/or a DC voltage in the range of 130 volts to 1500 volts, and preferably an AC voltage of essentially 400 volts or a DC voltage in the range of 650 volts to 700 volts. Similarly, the auxiliary energy flow may comprise an AC voltage of up to 50 volts and/or a DC voltage of up to 120 volts and/or an AC voltage in the range of 0.01 volts to 50 volts and/or a DC voltage in the range of 0.01 volts to 120 volts, and preferably a DC voltage of essentially 24 V or 48 V.

The contacting between the respective contact reception element and the corresponding contacting element may, for example, be designed as a pin-socket-contacting, as spring contacting, in particular as a spring clip, and/or as area contacting and, in particular, also comprise combinations thereof. In particular, the contacting between the first contact reception element 12 and the corresponding contacting element of the functional module is designed differently than the contacting between the second contact reception element 14 and the corresponding contacting element of the functional module, or the two types of contacting are different.

In particular, the functional module not shown here in this FIG. 1 may be inserted in the insertion direction ER indicated by the arrow, which is substantially parallel to the first layer E1 and substantially perpendicular to the second layer E2, in order to contact the first contact reception element 12, the second contact reception element 14 and optionally the third contact reception element 16, as will now be described in connection with the further figures.

According to a further embodiment variant, according to FIG. 1, the first layer E1′ may differ from the second layer E2 in that the first layer E1′ is provided parallel to but offset from the second layer E2 in such a way that the contact reception elements 12, 14, 16 in the first and second layers E1′, E2 contact the (inserted) functional module 20 from opposing sides. For this purpose, for example, the first contact reception element 12 may be provided in the first layer E1′ in order to provide a main energy flow via the first contacting element 22 to the functional module 20. In this case, the contact reception element 12 is attached, for example, to an adapter piece 30 or the like in the first layer E1′. The further contact reception elements 14, 16 may be provided in the second layer E2. The second contact reception element 14 may provide the auxiliary flow to the functional module 20 via the second contacting element 24 and the third contact reception element 16 may provide the data flow to the functional module 20 via the third contacting element 26 (see FIG. 2).

FIG. 2 illustrates a perspective view of a connecting device 10 according to further embodiments of the invention.

In this FIG. 2, it is shown by way of example that the first contact reception element 12 is designed as a spring contacting 12-1. Similarly, the contacting element 22 of the functional module 20 shown here in this FIG. 2, which corresponds to the first contact reception element 12, is designed as a spring contacting 22-1. The spring contacting 12-1 of the contact reception element 12 and the corresponding spring contacting 22-1 of the contacting element 22 are arranged and designed in such a way that they spring along the insertion direction ER or in the opposite direction. This also provides a tolerance in the insertion direction ER, which may compensate for movements of the functional module 20.

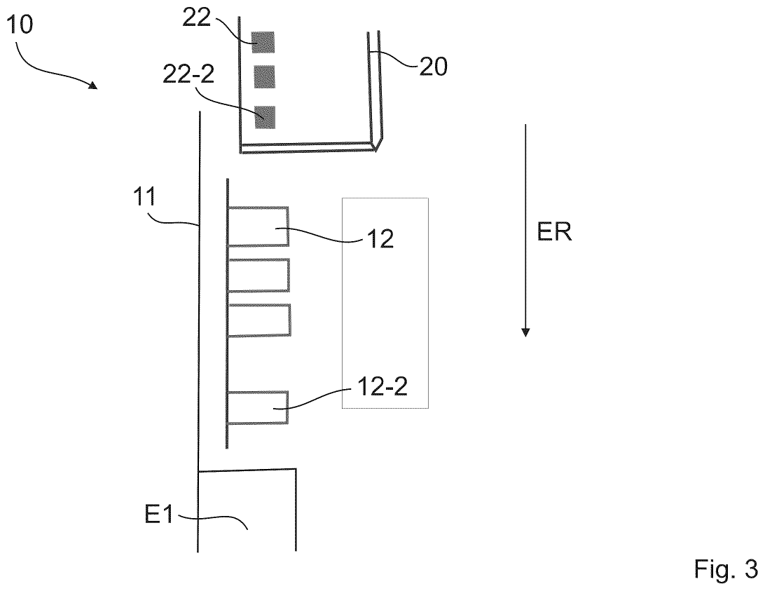

FIG. 3 illustrates a perspective view of a connecting device 10 according to further embodiments of the invention.

In this FIG. 3, it is shown by way of example that the first contact reception element 12 is designed as an area contacting 12-2. Likewise, the contacting element 22 of the functional module 20 corresponding to the first contact reception element 12 is designed as an area contacting 22-2. In particular, in this embodiment example, the second contact reception element not shown here is designed as a pin-socket-contacting, wherein a secure hold is ensured and the contacting on the first contact reception element 14 may be made possible only by a planar contact, in particular without further holding means.

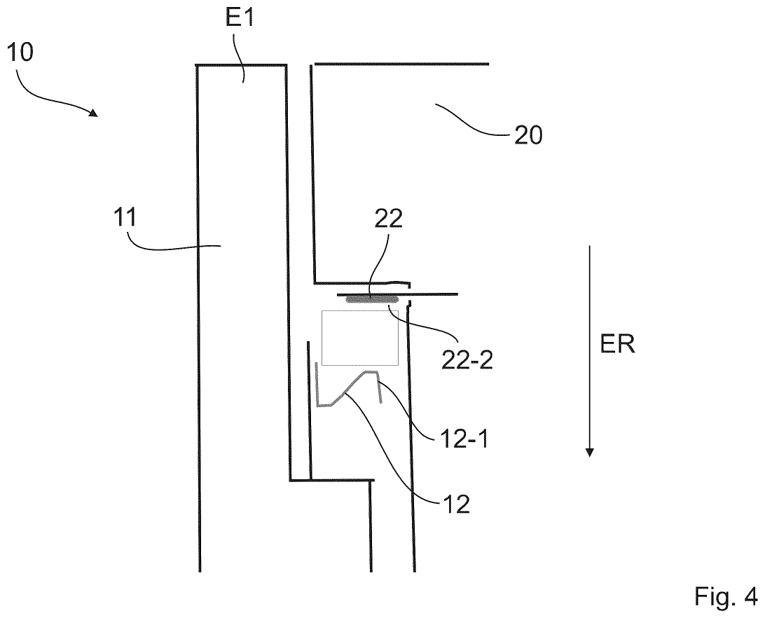

FIG. 4 illustrates a perspective view of a connecting device 10 according to further embodiments of the invention.

In this FIG. 4, it is shown by way of example that the first contact reception element 12 is designed as a spring contacting 12-1. However, the contacting element 22 of the functional module 20 corresponding to the first contact reception element 12 is designed as an area contacting 22-2. The spring contacting 12-1 of the contact reception element 12 and the corresponding area contacting 22-2 of the contacting element 22 are arranged and designed in such a way that they spring along the insertion direction ER or in the opposite direction. This also provides a tolerance in the insertion direction ER, which may compensate for movements of the functional module 20.

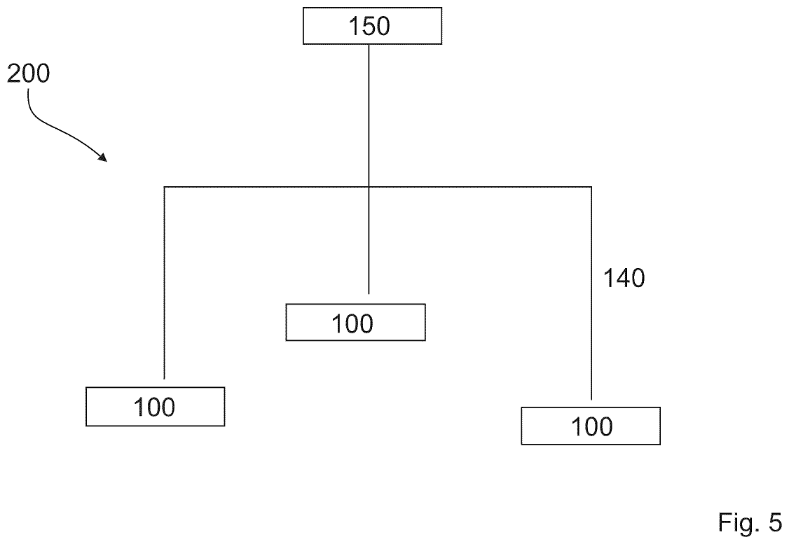

FIG. 5 schematically illustrates an industrial plant 200 with at least two automation platforms 100. The automation platforms 100 may each be designed as a decentralized automation platform 100, and may be designed accordingly to each provide partial automation functions and, in particular, a part of an overall control for the automation of the industrial plant 200. For this purpose, the automation platforms 100 may be arranged decentrally in the field of the plant 200, in particular in order to jointly replace a function of a central control cabinet, wherein the automation platforms 100 are connected to each other and/or to a central control system 150 via a fieldbus 140.

The foregoing explanation of the embodiments describes the present invention solely by way of examples. Of course, individual features of the embodiments may be freely combined with one another, provided that this is technically expedient, without departing from the scope of the present invention.

### LIST OF REFERENCE SYMBOLS

10 Connecting device
11 First leg
12 First contact reception element
13 Second leg
14 Second contact reception element
16 Third contact reception element
20 Functional module
22 First contacting element
24 Second contacting element
26 Third contacting element
30 Cover, adapter piece
100 Automation platform
12-1 Spring contacting
12-2 Area contacting
22-1 Spring contacting
22-2 Area contacting
ER Insertion direction
E1 First layer
E2 Second layer
W Angle

1. A connecting device for an automation platform, comprising:
a first contact reception element, which is arranged in a first layer and which is designed to provide a first contacting with a first contacting element of a functional module corresponding to the first contact reception element; and
a second contact reception element, which is arranged in a second layer, which differs from the first layer, and which is designed to provide a second contacting with a second contacting element of the functional module corresponding to the second contact reception element;
wherein the first contact reception element is designed to provide at least one of a main energy flow, an auxiliary energy flow and a data flow via the first contacting element to the functional module and wherein the second contact reception element is designed to provide at least one further of a main energy flow, an auxiliary energy flow and a data flow via the second contacting element to the functional module.

2. The connecting device according to claim 1, characterized in that
the first contact reception element and/or the second contact reception element is designed to form a plug connection.

3. The connecting device according to claim 1,
characterized in that
the first contact reception element and/or the second contact reception element comprises a spring contacting.

4. The connecting device according to claim 3,
characterized in that
the first layer and the second layer are arranged relative to one another in such a way that they enable the functional module to be inserted in an insertion direction which is essentially perpendicular to one of the first layer and the second layer, and wherein the spring contacting is arranged and designed in such a way that it springs in the insertion direction.

5. The connecting device according to any one of claim 3, characterized in that
the spring contacting is designed as a spring clip.

6. The connecting device according to claim 1,
characterized in that
the first contact reception element and/or the second contact reception element comprises a surface contacting.

7. The connecting device according to claim 1,
characterized in that
the main energy flow comprises an AC voltage of up to 1000 volts and/or a DC voltage of up to 1500 volts and/or an AC voltage in the range from 70 volts to 1000 volts and/or a DC voltage in the range from 130 volts to 1500 volts
and/or
the auxiliary energy flow comprises an AC voltage of up to 50 volts and/or a DC voltage of up to 120 volts and/or an AC voltage in the range from 0.01 volts to 50 volts and/or a DC voltage in the range from 0.01 volts to 120 volts,

8. The connecting device according to claim 1,
characterized in that
the first contact reception element is formed differently from the second contact reception element.

9. An automation platform comprising:
a connecting device and
at least one functional module,
wherein the connecting device comprises:
a first contact reception element, which is arranged in a first layer and which is designed to provide a first contacting with a first contacting element of a functional module corresponding to the first contact reception element; and
a second contact reception element, which is arranged in a second layer, which differs from the first layer, and which is designed to provide a second contacting with a second contacting element of the functional module corresponding to the second contact reception element:
wherein the first contact reception element is designed to provide at least one of a main energy flow, an auxiliary energy flow and a data flow via the first contacting element to the functional module and wherein the second contact reception element is designed to provide at least one further of a main energy flow, an auxiliary energy flow and a data flow via the second contacting element to the functional module.

10. The automation platform according to claim 9, comprising a further connecting device, wherein each of the connecting devices is connectable to at least one functional module each, wherein the connecting devices are designed to provide at least one of the main energy flow, the auxiliary energy flow and the data flow to the functional modules.

11. The automation platform according to claim 10, characterized in that
the connecting devices are arranged and designed in relation to each other in such a way that they provide at least one of the main energy flow, the auxiliary energy flow and/or the data flow serially to the functional modules.

12. The automation platform according to claim 9,
further comprising a bridge element which is connected to one of the connecting devices and which is adapted to receive at least one of the main energy flow, the auxiliary energy flow and the data flow and to provide it to a further connecting device.

13. The automation platform according to claim 9, characterized in that
the connecting device further comprises:
a third contact reception element which is arranged in the first layer or in the second layer or in a third layer and which is designed to provide a third contacting with a third contacting element of the functional module corresponding to the third contact reception element, wherein the first contact reception element is designed to provide a main energy flow via the contacted first contacting element to the functional module, and in that the second contact reception element is designed to provide an auxiliary energy flow via the contacted second contacting element to the functional module, and in that the third contact reception element is designed to provide a data flow via the contacted third contacting element to the functional module.

14. The automation platform according to claim 13, characterized in that
the first layer differs from the second layer in that the first layer is arranged parallel and/or offset to the second layer in such a way that the contact reception elements in the first and second layer contact the functional module via the contacting elements on opposing sides of the functional module, one or two of the contact reception elements being attached for this purpose to a separate coupling/adapter/cover element, which is designed to be attached to the functional module only after the other contact reception element(s) has/have made contact.

15. An industrial plant comprising at least two automation platforms,
each comprising a connecting device and at least one functional module, wherein the respective connecting device comprises:
a first contact reception element which is arranged in a first layer and which is designed to provide a first contacting with a first contacting element of the functional module corresponding to the first contact reception element; and
a second contact reception element, which is arranged in a second layer, which differs from the first layer, and which is designed to provide a second contacting with a second contacting element of the functional module corresponding to the second contact reception element;
wherein the first contact reception element is designed to provide at least one of a main energy flow, an auxiliary energy flow and a data flow via the first contacting element to the functional module and wherein the second contact reception element is designed to provide at least one further of a main energy flow, an auxiliary energy flow and a data flow via the second contacting element to the functional module,
characterized in that
the automation platforms are each designed as a decentralized automation platform and are designed accordingly to provide partial automation functions in each case and, the automation platforms being arranged decentrally in the field of the plant, the automation platforms being connected to one another and/or to a central control system via a field bus.

16. The connecting device according to claim 1, wherein the second layer is angled with respect to the first layer.

17. The connecting device according to claim 4, wherein the spring contacting provides a tolerance in the insertion direction.

18. The connecting device according to claim 1, wherein the spring clip is arranged and designed to be spread by a spreading element of the functional module.

19. The connecting device according to claim 7, wherein at least one of:
(a) the main energy flow comprises an AC voltage of essentially 400 volts or a DC voltage in the range from 650 V to 700 V;
(b) the auxiliary energy flow comprises a DC voltage of essentially 24 V or 48 V;
(c) the data flow comprises at least one or more signals for data exchange; and/or
(d) the data flow comprises at least one or more signals for data exchange for providing a data bus and/or a field bus.

20. The connecting device according to claim 1, wherein the contact reception elements in the first and second layer contact the functional module via the contacting elements on an upper and a lower side or on two opposing outer sides.
